(19) United States
(12) Patent Application Publication
(10) Pub. No.: US 2016/0320359 A1
(43) Pub. Date: Nov. 3, 2016

(54) SYSTEM AND METHOD FOR MONITORING CONTAMINATIONS

(71) Applicant: TAIWAN SEMICONDUCTOR MANUFACTURING CO., LTD., HSINCHU (TW)

(72) Inventors: Tzu-Sou CHUANG, Hsinchu City (TW); Chi-Wen KUO, Taipei City (TW)

(21) Appl. No.: 14/700,140

(22) Filed: Apr. 29, 2015

(51) Int. Cl. G01N 30/96; H01L 21/66; G01N 27/20; G01N 1/28; G01N 27/06; H01L 21/67; G01N 1/10

(52) U.S. Cl. CPC G01N 30/96; H01L 21/67288; H01L 22/10; G01N 1/10; G01N 1/28; G01N 27/06; G01N 27/20

(57) ABSTRACT

A system for monitoring contaminations includes a moisture-containing chilating gas supply adapted to provide a moisture-containing chilating gas mixing with a purge gas evacuated from a chamber, a cooling device adapted to condense a mixed gas comprising the moisture-containing chilating gas and the purge gas into a droplet, an impinger adapted to collecting the droplet on a sampling tube wall and in the mixed gas, and a conductivity meter. The droplet is dissolved in a DI water in the impinger, and the conductivity meter measures a conductivity of a fluid including the droplet and the DI water in the impinger. The fluid with contaminations has higher conductivity than that without contaminations, such that the polluted chamber can be selected.

### BACKGROUND

In semiconductor processing, a large portion of the yield losses is attributed to contaminations by particles and films of various natures. The contaminants may be organic or inorganic moleculars and particles. Some contaminants are generated from condensed organic vapors, solvent residues, photoresist or metal oxide compounds.

Typical problems and the detrimental effects caused by contaminants are poor adhesion of deposited layers, poor-formation of LOCOS oxides, or poor etching of the underlying material. The electrical properties and the stability of devices built on the semiconductor substrate may also be seriously affected by ionic based contaminants. The various forms of contaminants therefore not only reduce the product yield but also degrade the reliability of the devices built.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic cross-sectional view of a wafer containing apparatus, in accordance with some embodiments.

FIG. 2 is a schematic view of the system for monitor contaminations, in accordance with some embodiments.

FIG. 3 is a schematic view of a moisture-containing chilating gas supply, accordance with some embodiments.

FIG. 4 is a block diagram of a system for monitoring contamination, in accordance with some embodiments.

FIG. 5 is a schematic view of a containing apparatus, in accordance with some embodiments.

FIG. 6 is a flow chart of a method for monitoring contaminations, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In a semiconductor manufacturing process, wafers are processed in a clean room for improved yield and quality. However, when the trends of high integration of devices and circuit miniaturization along with the adoption of larger wafers have progressed, it has become difficult to manage small dusts in an entire clean room in view of costs as well as from a technical point of view. Accordingly, instead of increasing the cleanliness of the entire interior of such a clean room, a system that incorporates “mini-environment system,” which locally increases the cleanliness only around wafers, has been adopted recently for transporting and otherwise processing wafers. The mini-environment system includes a storage container known as a front-opening unified pod (FOUP) for transporting and retaining a wafer in a highly clean environment. The FOUP has an opening door in a front portion through which the semiconductor wafer is inserted into or taken out of the jig. The FOUP includes a chamber constructed of a shell which is a holding part for receiving the semiconductor wafer and a door which is a part for opening or closing the shell. The FOUP holds the semiconductor wafer in a hermetically enclosed space to protect the semiconductor wafer from foreign matters or chemical pollution in the atmosphere.

Usually, the FOUP is molded of plastics and the hermeticity between the shell and the door is kept by sealing made of rubber or the like. The sealing will cause leakage and both the plastic and rubber will outgassing AMC contaminants. outside air easily intrudes into the FOUP when transporting the wafers in and out of the FOUP . Hence, the humidity and oxygen concentration in the FOUP tends to increase with the lapse of time.

Moreover, in a case where the semiconductor wafer having a resist deposited thereon is stored in the FOUP, an organic solvent evaporated from the resist is deposited on the inner wall of the shell. Hence, even after the semiconductor wafer having the resist deposited thereon is removed, the resist deposited on the inner wall of the shell is again evaporated to pollute the atmosphere in the FOUP. Moisture, oxygen, and contaminants in the FOUP may pollute the semiconductor wafer and cause to yield loss.

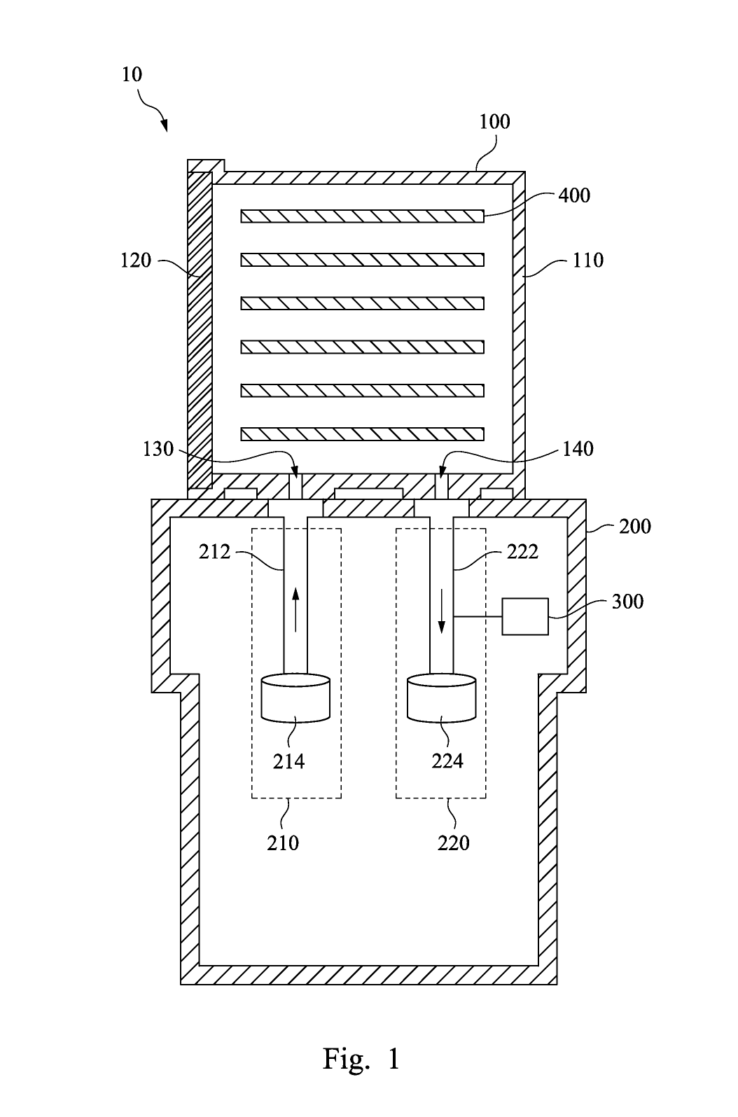

FIG. 1 is a schematic cross-sectional view of a wafer containing apparatus, in accordance with some embodiments. The FOUP 10 includes a chamber 100 constructed of a shell 110 and a door 120, a purge load port 200 connected to the chamber 100, and a system 300 for monitoring contaminations in the purge load port 200.

The door 120 is disposed at an opening of the shell 110. The door 120 and the shell 110 construct the chamber 100 for containing wafers 400 within. The purge load port 200 is a mechanism provided to introduce a purge gas, for example, a nitrogen gas or dry air with extremely low humidity into the chamber 100 to replace the atmosphere in the chamber 100 with the purge gas. The chamber 100 has a vent inlet 130 and a vent outlet 140. The purge load port 200 is connected to the chamber 100 through the vent inlet 130 and the vent outlet 140.

The purge load port 200 includes a purge gas supply 210 and a purge gas evacuation device 220. The purge gas supply 210 is connected to the vent inlet 130 to provide the purge gas into the chamber 100. The purge gas evacuation device 220 is connected to the vent outlet 140 to evacuating the purge gas from the chamber 100. The purge gas supply 210 includes a purge conduit 212 which is provided in gas communication with the vent inlet 130, a purge valve which may be manual or electric, is provided in the purge conduit 212 for selectively allowing flow of the purge gas, such as clean, dry air, atmospheric air or nitrogen or other purge gas through the purge conduit 212 and into the chamber 100. In some embodiments, purge gas source 214 is connected to the input of the purge valve. The purge gas evacuation device 220 provides an evacuation of the chamber 100 to replace the gas within the chamber 100 with the purge gas. The purge gas evacuation device 220 includes an evacuation conduit 222 connected to the vent outlet 140, and a vacuum pump 224. The purge gas collectively directs the processing gas to flow towards the vacuum pump. In some embodiments, the evacuation can be continued by the purge gas evacuation device 220 during boat-in/out (or wafer loading/unloading) processes for preventing the back-flow of the contaminations.

As described above, some unwanted contaminations might exist in the chamber 100. Therefore, the present disclosure provides the system 300 to extract the contaminations in the chamber 100 for monitoring and further analysis.

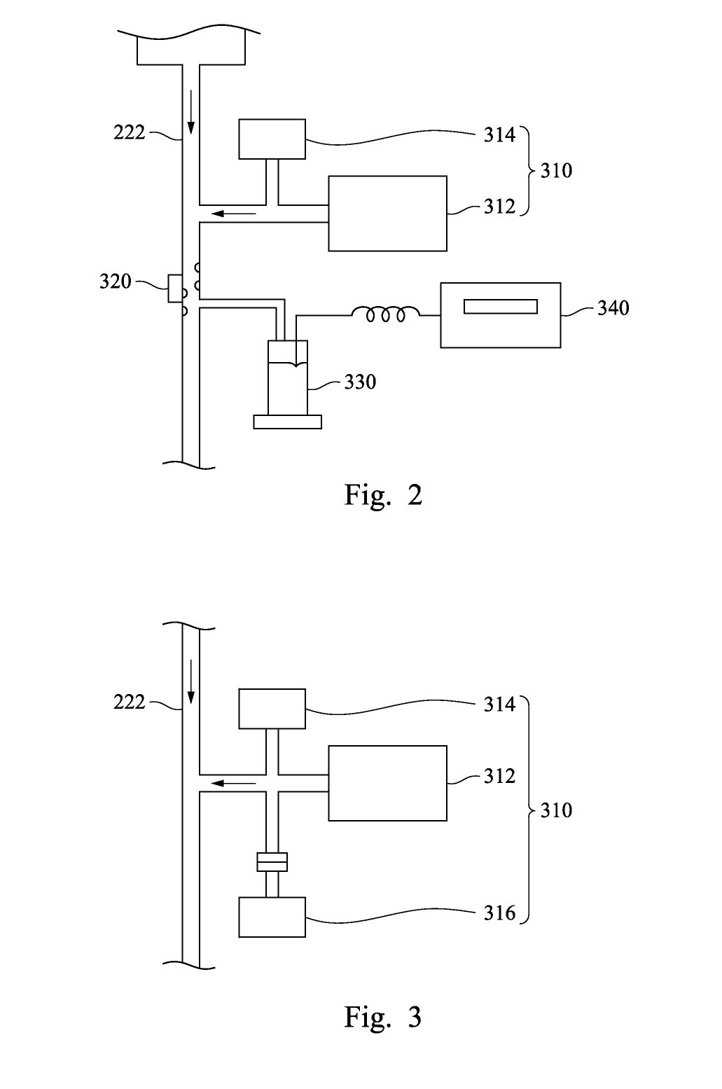

FIG. 2 is a schematic view of the system for monitor contaminations, in accordance with some embodiments. The system 300 for monitoring contaminations includes a moisture-containing chilating gas supply 310, a cooling device 320, an impinger 330, and a conductivity meter 340. The moisture-containing chilating gas supply 310 is disposed connected to the evacuation conduit 222 to provide a moisture-containing chilating gas mixing with the purge gas evacuated from the chamber 100. The cooling device 320 is utilized to reduce the temperature of the mixed gas, which includes the moisture-containing chilating gas and the purge gas. The cooled mixed gas is condensed by the cooling device 320 and becomes a droplet adhered on the sidewall of the evacuation conduit 222. In some embodiments, the evacuation conduit 222 is a metal or plastic tube, and the cooling device 320 includes a thermoelectric cooling chip fastened on the metal or plastic tube.

The impinger 330 is utilized for collecting the droplet in the evacuation conduit 222. The impinger 330 contains a DI water (de-ionized water) within, and the droplet condensed by the mixed gas is dissolved in the DI water. The conductivity meter 340 is utilized for measuring the conductivity of the fluid, i.e. the fluid of the droplet dissolved in the DI water. The conductivity of the fluid in the impinger 330 can be leveled in order to determined whether the FOUP is polluted or not. The conductivity meter 340 is electrically connected to a processor, such that the process of leveling the fluid can be performed automatically.

For instance, if the FOUP is polluted, the contaminations are existed in the chamber 100 (see FIG. 1) and are carried by the purge gas when the purge gas is evacuated from the chamber 100. The moisture-containing chilating gas is mixed with the purge gas having the contaminations. The mixed gas including the moisture and the chilated contaminations is condensed by the cooling device 320 and becomes droplet. The moisture-containing chilating gas captures the chilated contaminations, and is condensed when the mixed gas is cooled. The chilated contaminations become particles carried by the droplet when the mixed gas including the moisture is condensed. The droplet in the liquid state is further collected by the impinger 330. The droplet and the particles carried by the droplet are dissolved in the DI water. Therefore, the conductivity of the fluid collected from a polluted FOUP has a higher conductivity than that from a clean FOUP. Namely, if the conductively of the fluid in the impinger is higher than a predetermined level, the FOUP which the fluid is collected from can be determined as being polluted.

The sensitivity of determining whether the FOUP is polluted or not can be adjusted according to different requirements. For example, when the FOUP is utilized in a clean room, which has high requirement of cleaning, the sensitivity of determining whether the FOUP is polluted is relatively high. In some embodiments, the FOUP is clean and is not polluted, thus the conductivity of the fluid in the impinger 330 is substantially equals to the conductivity of DI water, which is very low and is about zero. Therefore, when the conductivity of the fluid in the impinger 330 is about zero, the FOUP thereof can be determined clean and is not polluted.

By using the process of measuring the conductivity of the fluid in the impinger 330, the polluted FOUP can be selected rapidly. The system 300 extracting the contaminations for monitoring and further analysis can be assembled in each and every purge load ports for FOUPs to achieve the purpose of full-channel inspection. The system 300 for monitoring contaminations can real-time monitor the polluting state of the FOUPs from the limited volume of the purge gas evacuated from the FOUPs. The contaminations are captured by the moisture-containing chilating gas and are condensed in a very short time (about milliseconds), thus the efficiency of sampling can be highly improved by using the system 300.

In some embodiments, the contaminations in the purge gas can be captured by the moisture-containing chilating gas. The moisture-containing chilating gas supply 310 includes a clean air source 312 with chilating agents and a moisture source 314. The clean air source 312 provides a clean air, such as and a clean room air (CR air). In some embodiments, the moisture provided by the moisture source 314 is mixed with the clean air before entering the evacuation conduit 222, and the moisture is carried into the evacuation conduit 222 while the clean air is flew into the evacuation conduit 222.

The evacuated purge gas including the contaminations is chilated and moistened by the moisture-containing chilating gas. The mixed gas with high humidity passes through a low-temperature conduit cooled by the cooling device 320. The humidity saturation of the mixed gas is reduced when the mixed gas full of moisture passes through the low-temperature conduit and is cooled. Therefore, the mixed gas is condensed by a super saturation and becomes droplets with a diameter of about 800 nm. Thus, the contaminations are gathered and carried by droplets.

The space in the FOUP, such as a 450 mm FOUP, is limited. Therefore, the volume of the evacuated purge gas for sampling is also limited. The system 300 for extracting contaminations for monitoring and analysis includes using chemical methodology to capture the contaminations with the moisture-containing chilating gas and further using physical methodology to condense the mixed gas into droplets. The droplets are easily collected by the impingers 330, such that the sampling time is shortened, comparing with directly collecting the contaminations in the purge gas.

The contaminations from FOUP interior can be acidic, alkaline, organic gaseous contaminants, or combinations thereof. In some embodiments, the types of the contaminations are predictable. For example, the FOUPs may convey the wafers from an etching chamber directly or indirectly. The types of the contaminations can be the agents utilized in the etching process or the particles generated during the etching process.

In some embodiments, the etching process is a wet etching process using acidic solutions. The contaminations thereof can include particles of the substrate with acidic solution. The particles of the substrate can include dielectric material, such as silicon (Si), siliconcarbide (SiC), silicon dioxide (SiO₂), or the likes, and/or conductive materials. The acidic solutions can be ferric chloride (FeCl₃), hydrochloric acid (HCl), hydroiodic acid (HI), hydrobromic acid (HBr), or the like. In some embodiments, the etching process is a wet etching process using alkaline solutions. The contaminations thereof can include particles of the substrate with alkaline solution. The particles of the substrate can include dielectric material, such as silicon (Si), siliconcarbide (SiC), silicon dioxide (SiO₂), or the like. The alkaline solution can be sodium hydroxide (NaOH), potassium (KOH), or the likes. In some embodiments, the etching process is a dry etching process using reactive gases. The contaminations thereof can include the reactive gasses and the particles for being removed. The particles of the substrate can include dielectric materials and /or conductive materials, such as metallic conductive material or transparent conductive material. The reactive gases can be any one of fluorine (F₂), nitrogen trifluoride (NF₃), tetrafluoromethane (CF₄), hexafluoroethane (C₂F₆), octafluoropropane (C₃H₈), hydrogen fluoride (HF), chlorine (Cl₂), tetrachloromethane (CCl₄), hydrogen chloride (HCl), diclorosilane (SiH₂Cl₂), tetrachloro-difluoro ethane (C₂F₂Cl₄), trifluoromethane (CHF₃), bromine (Br₂), hydrogen bromide (HBr).

When the types of the contaminations are predictable, the sampling efficiency can be further improved by adjusting the components of the moisture-containing chilating gas. Details thereof are discusses in FIG. 3, which is a schematic view of a moisture-containing chilating gas supply, according to some embodiments. The moisture-containing chilating gas supply 310 includes a clean air source 312, a moisture source 314, and chelating agent source 316. In some embodiments, the chelating agent provided by the chelating agent source and the moisture provided by the moisture source are mixed with the clean air before they enter the evacuation conduit 222. The moisture and the chelating agents are carried into the evacuation conduit 222 when the clean air flows into the evacuation conduit 222.

The chelating agents are utilized to capture and react with the contaminations. The chelating agents are in gas state, such that the contaminations can be captured by the chelating agents directly. The chemical reactants of the contaminations and the chelating agents are in the state of particles, and the particles are carried by the mixed gas. The mixed gas full of moisture is cooled and becomes droplets, in which the droplets are further collected by the impinger. The particles carried by the droplets are also collected by the impinger and are dissolved in the DI water in the impinger.

The chelating agents can be selected according to the processes executed on the wafers, which are conveyed by the FOUPs. For example, the wafers can be processed by a wet-etching process using acidic solution, such as hydrochloric acid. The chelating agents thereof can be an alkaline agents, such as ammonia gas. The ammonia is reacted with the hydrochloric acid, and the chelating particle thereof includes ammonium chloride, which is an electrolyte and changes the conductivity after being dissolved in water. Therefore, the conductivity of the droplets collected from the FOUP containing the contaminations is much higher than the droplets collected from the FOUP without contaminations. The conductivity of the droplets from the clean FOUP can be obtained by repeating and averaging plural blank examples. The conductivity of the droplets from the clean FOUP can be recorded, such that when the FOUP has a conductivity higher than the recorded value (or a predetermined value corresponding to the recorded value), the FOUP can be determined being polluted. Also, the sensitivity of the system 300 can be adjusted by controlling the predetermined value.

In some embodiments, the wafers are processed by a wet-etching process using alkaline solution. The chelating agents thereof can be acidic agents, such as hydrochloric acid, to react with the alkaline contaminations. The acidic chelating agents capture the alkaline contaminations and become particles. The particles are carried by the condensed droplets and are further collected by the impinger. The particles are electrolytes, such that the conductivity of the fluid in the impinger is changed when the particles are dissolved in the impinger. The state of the FOUP, i.e. clean or polluted, can be determined by the corresponding conductivity.

The systems 300 are assembled to the purge load port for real time monitoring the state of the FOUPs on the purge load port and selecting the polluted FOUPs. The process from mixing the gases to selecting the polluted FOUP can be finished within one minute, which has high efficiency and provides full-channel inspection for the FOUPs. Additionally, in some embodiments, the chelating agent source 316 can be detachably assembled, such that the type of the chelating agent source 316 can be varied according to the type of the contaminations.

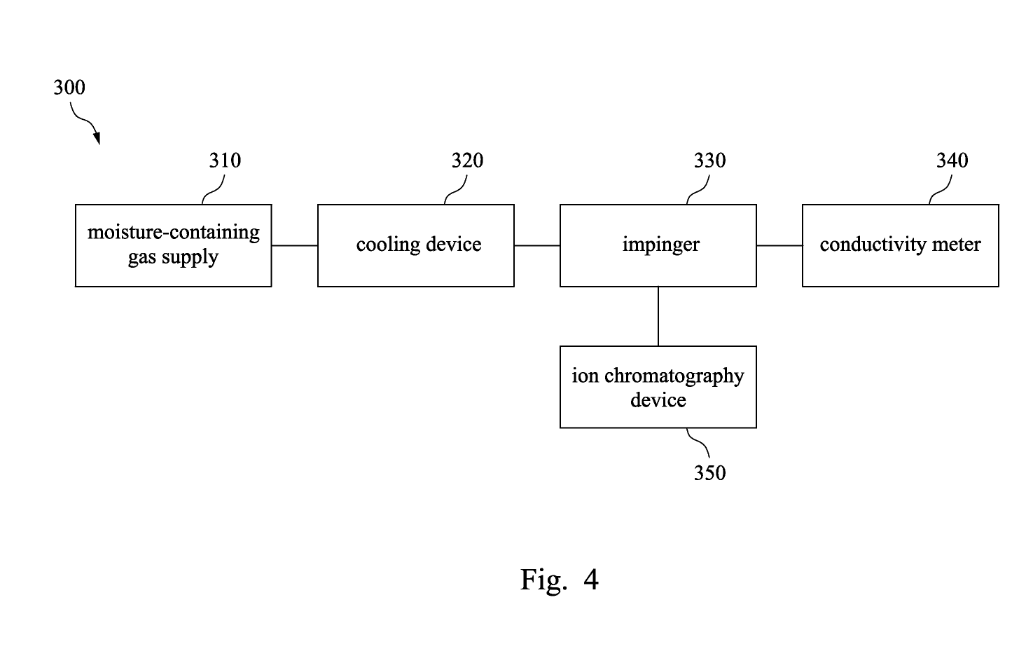

Referring to FIG. 4, which is a block diagram of a system for monitoring contamination, in accordance with some embodiments. In some embodiments, there is a need to analysis the type of the contaminations. The system 300 includes a moisture-containing chilating gas supply 310, a cooling device 320, an impinger 330, a conductivity meter 340, and an ion chromatography device 350.

The moisture-containing chilating gas supply 310 is connected to the evacuations conduit and provides moisture-containing chilating gas into the evacuation conduit. In some embodiments, the moisture-containing chilating gas includes merely moisture and clean air. In some embodiments, the moisture-containing chilating gas includes clean air, moisture, and chelating agents.

The moisture-containing chilating gas is mixed with the purge gas, and the mixed gas thereof is cooled by the cooling device 320. The mixed gas full of moisture and reactant are condensed and becomes droplets. If the FOUP is polluted, the reactant of contaminations are adhered on and carried by the droplets. The droplets are collected by the impinger 330, and the droplet, or the droplets with the contaminations in some embodiments, are dissolved in the DI water in the impinger 330. The conductivity of the fluid in the impinger 330 is measured by the conductivity meter 340. In this step, the polluted FOUP(s) can be selected because of having the relative high conductivity. When the FOUP is determined polluted, the sample (e.g. the fluid including the contaminations) of the corresponding impinger 330 can be sent to the ion chromatography device 350.

The ion chromatography device 350 are utilized to analysis the contaminations. Ion chromatography is a technique for the analysis of sample in an eluent solution containing an electrolyte (e.g. the contaminations). The sample solution is injected into a chromatographic separation zone, in the form of an ion exchange column, and directed through an eluent suppression stage, and a detector, typically a conductivity detector. Ions of the injected sample are separated on and eluted from a separation column. In the suppression stage, electrical conductivity of the eluent electrolyte, but not that of the separated ions, is suppressed. This can be accomplished so long as the separated ions are not derived from very weak acids or bases and so can be determined by conductivity detection. In some embodiments, the sample is introduced, either manually or with an autosampler, into a sample loop of known volume. A buffered aqueous solution known as the mobile phase carries the sample from the loop onto a column that contains some form of stationary phase material. This is typically a resin or gel matrix consisting of agarose or cellulose beads with covalently bonded charged functional groups. The target analytes (anions or cations) are retained on the stationary phase but can be eluted by increasing the concentration of a similarly charged species that will displace the analyte ions from the stationary phase. For example, in ion exchange chromatography, the positively charged analyte could be displaced by the addition of positively charged sodium ions. The analytes of interest then be detected by some means, typically by conductivity or UV/Visible light absorbance.

However, the time and the cost of using ion chromatography device 350 to analysis the contaminations are high. Therefore, only the sample from the polluted FOUP is sent to the ion chromatography device 350. Namely, all of the FOUPs assembled on the purge load port can be primary selected by using the conductivity meter 340 measuring the conductivity of the sample in the corresponding impinger 330, but only the sample from the polluted FOUP, which has the conductivity higher than the predetermined level, is sent to the ion chromatography device 350 for analyze.

After the contaminations are recognized by the ion chromatography process, the problem or the pollution source during the manufacture can be found by matching the contaminations with the agents utilized during the manufacture. Thus the user can easily fix the problem since the station of the problem is obtained and even take precaution before the defect formation on wafers.

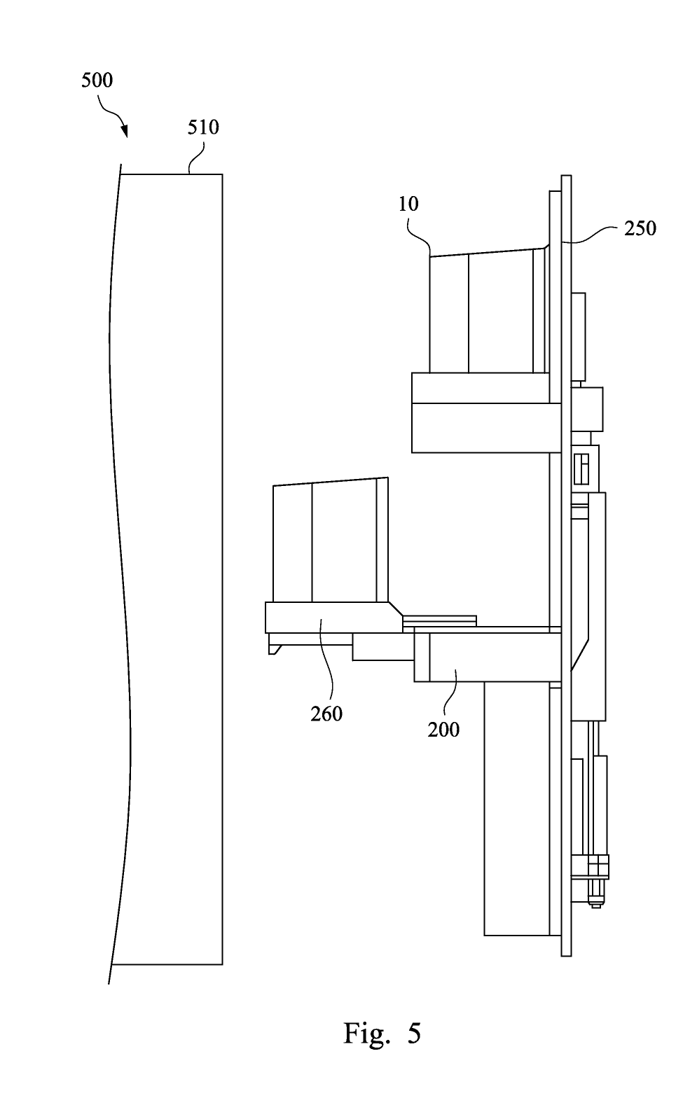

The system 300 for monitoring contaminations is not only utilized for FOUPS, but also utilized in other designs cooperated with the purge load port, such as a equipment front end module (EFEM). For example, FIG. 5 is a schematic view of a wafer containing apparatus, in accordance with some embodiments. The wafer containing apparatus is an EFEM 500, which includes a wafer transport chamber 510, FOUPs 10, and a purge load port 200. The purge load port 200 is used as an interface for allowing the FOUP 10 to insert/remove wafers into/from the wafer transport chamber 510 and for passing/receiving the FOUP 10 itself to/from the FOUP transport device of the purge load port 200. In the EFEM system, there is still a need to keep the cleanness to a predetermined level.

The FOUP transport device of the purge load port 200 includes a rail 250 and a transport table 260. The rail 250 stands on the base of the purge load port 200 and allows the FOUP 10 moving vertically along the rail 250. The transport table 260 is utilized to transport the FOUP 10 between the purge load port 200 and the wafer transport chamber 510.

The EFEM 500 may further include the system for monitoring contamination as previously discussed. The system for monitoring contaminations can be assembled in the transport table 260 or any suitable position in the purge load port.

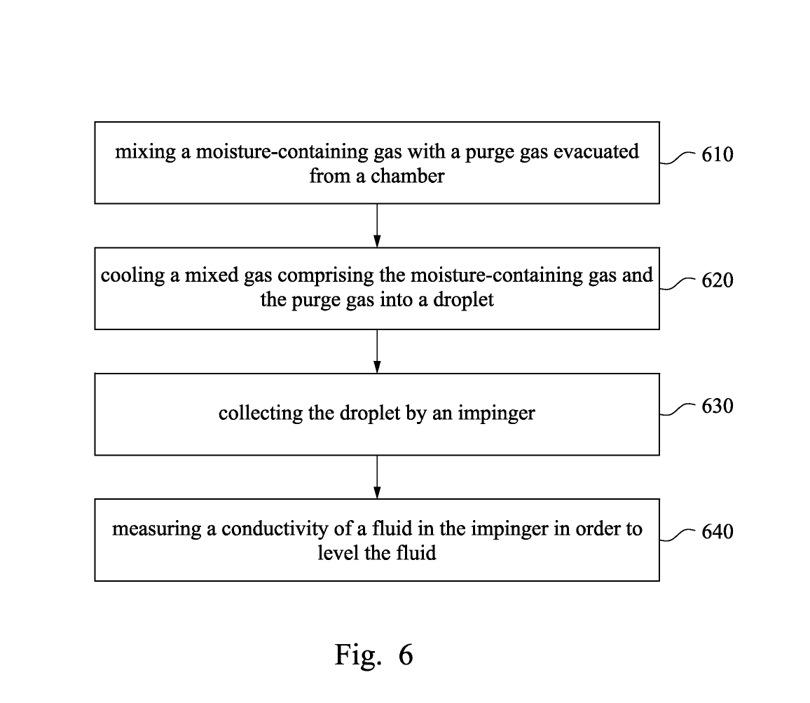

FIG. 6 is a flow chart of a method for monitoring contaminations, in accordance with some embodiments. The method begins at step 610, in which a moisture-containing chilating gas is mixed with a purge gas evacuated from a chamber (e.g. the FOUP or the FOUP of the EFEM). In some embodiments, the moisture-containing chilating gas can include merely the clean air and the moisture. In some embodiments, the moisture-containing chilating gas includes the clean air, the moisture, and the chelating agents, such as ammonia or hydrogen chloride gas. In such embodiments, the contaminations in the purge gas may chelate with the chelating agents in the moisture-containing chilating gas thereby forming reactant of particles.

In step 620, the mixed gas including the moisture-containing chilating gas and the purge gas is cooled and becomes a droplet. The mixed gas is cooled by a cooling device, such as a thermoelectric cooling chip. If the purge gas includes contaminations, the contaminations or the particles of chelating the contaminations with the chelating agents in the moisture-containing chilating gas may adhere on and carried by the droplet.

In step 630, the droplet is collected by the impinger. The impinger has DI water therein, and the droplet is dissolved in the DI water. In some embodiments, the contaminations are carried by the droplet, and the contaminations or particles thereof are also dissolved in the DI water, such that the conductivity of the fluid in the impinger is changed.

In step 640, the conductivity of the fluid in the impinger is measured by, for example, a conductivity meter. The fluid can be leveled according to the conductivity of the fluid in the impinger. When the conductivity of the fluid is higher than a predetermined level, the FOUP that the fluid collected from is determined being polluted. In some embodiments, when the moisture-containing chilating gas includes merely the clean air and the moisture, the conductivity value of the predetermined level is approximate to zero. In some embodiments, when the moisture containing gas includes chelating agents, the conductivity value of the predetermined level is decided according to the blank examples (e.g. the value obtained from a clean FOUP). The sensitivity of the leveling the fluid can be adjusted according to different requirements of cleanness.

In some embodiments, the method optionally includes the step of analyzing the fluid in the impinger when the conductivity of the fluid in the impinger is higher than the predetermined level. Namely, only the contaminations of the fluid from the polluted FOUP is analyzed, such can save the time and cost of analysis. The step of analyzing the contaminations can be performed by, for example an ion chromatography process.

The system for monitoring contaminations is assembled at the purge load port to real time monitor the cleanness in the chamber (e.g. the FOUP or the FOUP of the EFEM). The contaminations in the purge gas are captured by the moisture-containing chilating gas rapidly and the mixed gas thereof is condensed into droplets. The droplets are dissolved in the DI water of the impinger, and the conductivity of the fluid is measured in order to determined whether the chamber is polluted or not. The time from mixing the gasses to determining can be finished within seconds. When the polluted FOUP is known, the contaminations can be sent to analysis in order to find the pollution source and fix the problem.

In some embodiments, a wafer containing apparatus includes a chamber adapted to contain a wafer within and comprising a vent outlet, a purge gas evacuation device connected to the vent outlet for evacuating a purge gas from the chamber, a moisture-containing chilating gas supply adapted to provide a moisture-containing chilating gas mixing with the purge gas evacuated from the chamber, a cooling device adapted to condense a mixed gas comprising the moisture-containing chilating gas and the purge gas into a droplet, and an impinger adapted to collect the droplet.

In some embodiments, a system for monitoring contaminations includes a moisture-containing chilating gas supply adapted to provide a moisture-containing chilating gas mixing with a purge gas evacuated from a chamber, a cooling device adapted to condense a mixed gas comprising the moisture-containing chilating gas and the purge gas into a droplet, an impinger connected to the cooling device and adapted to collecting the droplet, and a conductivity meter. The droplet is dissolved in a DI water in the impinger, and the conductivity meter measures a conductivity of a fluid including the droplet and the DI water in the impinger, in which the fluid with contaminations has higher conductivity than that without contaminations.

In some embodiments, a method for monitoring contaminations includes mixing a moisture-containing chilating gas with a purge gas evacuated from a chamber, cooling a mixed gas comprising the moisture-containing chilating gas and the purge gas into a droplet, collecting the droplet on a sampling tube wall and in the mixed gas by an impinger, and measuring a conductivity of a fluid in the impinger in order to level the fluid.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A wafer containing apparatus, comprising:
a chamber adapted to contain a wafer within and comprising a vent outlet;
a purge gas evacuation device connected to the vent outlet for evacuating a purge gas from the chamber;
a moisture-containing chilating gas supply adapted to provide a moisture-containing chilating gas mixing with the purge gas evacuated from the chamber;
a cooling device adapted to condense a mixed gas comprising the moisture-containing chilating gas and the purge gas into a droplet; and
an impinger adapted to collect the droplet.

2. The wafer containing apparatus of claim 1, wherein the impinger comprises a DI water, and the droplet is dissolved in the DI water.

3. The wafer containing apparatus of claim 2, further comprising a conductivity meter adopted to measure a conductivity of a fluid in the impinger after the droplet is dissolved.

4. The wafer containing apparatus of claim 1, wherein the purge gas includes contaminations, and the mixed gas is cooled such that the contaminations are carried by the droplet.

5. The wafer containing apparatus of claim 4, wherein the moisture-containing chilating gas comprises a moisture, a clean room air, and a plurality of chelating agents, wherein the chelating agents are adopted to react with the contaminations and become particles carried by the droplet.

6. The wafer containing apparatus of claim 5, wherein the chelating agents are ammonia or hydrogen chloride.

7. The wafer containing apparatus of claim 1, wherein the moisture-containing chilating gas comprises a moisture and a clean room air.

8. The wafer containing apparatus of claim 1, wherein the cooling device includes a thermoelectric cooling chip.

9. The wafer containing apparatus of claim 1, wherein the chamber is a front-opening unified pod (FOUP).

10. The wafer containing apparatus of claim 1, wherein the wafer containing apparatus is an equipment front end module (EFEM).

11. A system for monitoring contaminations, comprising:
a moisture-containing chilating gas supply adapted to provide a moisture-containing chilating gas mixing with a purge gas evacuated from a chamber;
a cooling device adapted to condense a mixed gas comprising the moisture-containing chilating gas and the purge gas into a droplet;
an impinger connected to the cooling device, the impinger adapted to collecting the droplet, wherein the droplet is dissolved in a DI water in the impinger; and
a conductivity meter adopted to measure a conductivity of a fluid comprising the droplet and the DI water in the impinger, wherein the fluid with contaminations has higher conductivity than that without contaminations.

12. The system for monitoring contaminations of claim 11, wherein the moisture-containing chilating gas comprises a moisture and a clean room air.

13. The system for monitoring contaminations of claim 11, wherein the moisture-containing chilating gas comprises a moisture, a clean room air, and a plurality of chelating agents.

14. The system for monitoring contaminations of claim 11, further comprising:
an ion chromatography device, wherein the fluid is selectively sent to the ion chromatography device according to the conductivity of the fluid.

15. The system for monitoring contaminations of claim 11, wherein the moisture-containing chilating gas supply is assembled at a purge load port connected to the chamber.

16. A method for monitoring contaminations, comprising:
mixing a moisture-containing chilating gas with a purge gas evacuated from a chamber;
cooling a mixed gas comprising the moisture-containing chilating gas and the purge gas into a droplet;
collecting the droplet on a sampling tube wall and in the mixed gas by an impinger; and
measuring a conductivity of a fluid in the impinger in order to level the fluid.

17. The method for monitoring contaminations of claim 16, wherein the collecting the droplet comprises dissolving the droplet in a DI water in the impinger.

18. The method for monitoring contaminations of claim 16, further comprising:
analyzing the fluid in the impinger when the conductivity of the fluid is higher than a level.

19. The method for monitoring contaminations of claim 18, wherein the analyzing the fluid is performed by an ion chromatography process.

20. The method for monitoring contaminations of claim 18, wherein the mixing the moisture-containing chilating gas with the purge gas comprising:
chelating contaminations in the purge gas with a plurality of chelating agents in the moisture-containing chilating gas.
